(19) United States
(12) Patent Application Publication
(10) Pub. No.: US 2013/0235677 A1
(43) Pub. Date: Sep. 12, 2013

(54) CIRCUIT FOR PARALLEL BIT TEST OF SEMICONDUCTOR MEMORY DEVICE

(71) Applicant: SAMSUNG ELECTRONICS CO., LTD., Suwon-si (KR)

(72) Inventor: Il Sang Park, Seoul (KR)

(73) Assignee: SAMSUNG ELECTRONICS CO., LTD., Suwon-si (KR)

(21) Appl. No.: 13/788,137

(22) Filed: Mar. 7, 2013

(30) Foreign Application Priority Data
Mar. 7, 2012 (KR) 10-2012-0023598

(51) Int. Cl. G11C 29/04

(52) U.S. Cl. CPC G11C 29/04
USPC 365/189.07

(57) ABSTRACT

A circuit for a Parallel Bit Test (PBT) of a semiconductor memory device is provided. The PBT circuit includes a comparator circuit and an inverter circuit. The comparator circuit is configured to generate a comparison signal responsive to a comparison indicating that first data to be written in a first group of the memory cells are the same as second data read from the first group of the memory cells. The comparison signal includes n periods and the value of the comparison signal during each period corresponds to a subset of the first group of the memory cells. The inverter circuit is configured to generate an inverted signal and a non-inverted signal in response to a clock signal. The inverted signal and non-inverted signal are formed as an inversion signal indicating whether at least one cell corresponding to each period is bad cell.

### CROSS-REFERENCE TO RELATED APPLICATIONS

This application claims the benefit of Korean Patent Application No. 10-2012-0023598, filed on Mar. 7, 2012, in the Korean Intellectual Property Office, the disclosure of which is incorporated herein in its entirety by reference.

### BACKGROUND

Example embodiments relate to a circuit for a parallel bit test of a semiconductor memory device.

In general, for semiconductor memory devices, an increase in storage capacity causes a test time to increase and causes a fail bit analysis to be difficult. Furthermore, to increase productivity within a limited production time, demands for test time reduction are increasing. Accordingly, a Parallel Bit Test (PBT) circuit capable of finding a fail bit address, is useful used in a semiconductor memory verification stage.

### SUMMARY

The present disclosure provides a semiconductor memory device including a Parallel Bit Test (PBT) circuit for verifying a quality of a semiconductor memory cell by using a signal, which is inversed at a constant interval.

According to one embodiment, there is provided a circuit for a Parallel Bit Test (PBT) of a semiconductor memory device including a memory cell array. The PBT circuit includes a comparator circuit and an inverter circuit. The comparator circuit is configured to generate a comparison signal responsive to a comparison indicating that first data to be written in a first group of the memory cells are the same as second data read from the first group of the memory cells. The comparison signal includes n periods. The value of the comparison signal during each period corresponds to a subset of the first group of the memory cells. The n is a natural number. The inverter circuit is configured to generate during each period, an inverted signal by inverting the comparison signal in response to either a rising edge or a falling edge of a clock signal, and to generate a non-inverted signal in response to the other of the rising edge or falling edge of the clock signal. The inverted signal and non-inverted signal are formed as an inversion signal indicating whether at least one cell corresponding to each period is bad cell.

According to another embodiment, there is provided a circuit of a semiconductor memory device. The circuit includes a comparator, an inverter circuit, and a determination circuit. The comparator is configured to generate a comparison signal responsive to a comparison indicating that first data to be written on a first group of memory cells of the memory cell array are the same as read data from the first group of the memory cells. The inverter circuit is configured to generate an inverted signal by inverting the comparison signal in response to either a rising edge or a falling edge of a clock signal, and to generate a non-inverted signal in response to the other of the rising edge or falling edge of the clock signal, the inverted signal and non-inverted signal forming an inversion signal. The determination circuit is configured to output the inversion signal as a determination signal in response to a strobe signal. The determination signal indicates whether at least one memory cell is a bad cell.

According to further another embodiment, there is provided a method for testing the operation of a semiconductor device. The method includes comparing first data to be written in a first group of the memory cells with read data stored in the first group of the memory cells, generating a comparison signal in response to the result of the comparing during first through nth periods, a subset of memory cells of the first group corresponding to each of the first through nth periods, respectively, and generating an inversion signal by inverting the comparison signal in response to either a rising edge or a falling edge of a clock signal, and to generate a non-inverted signal in response to the other of the rising edge or falling edge of the clock signal, the inverted signal and non-inverted signal forming an inversion signal. The inversion signal indicates whether at least one cell corresponding to each period is a failed memory cell.

### BRIEF DESCRIPTION OF THE DRAWINGS

Exemplary embodiments will be more clearly understood from the following detailed description taken in conjunction with the accompanying drawings in which:

FIG. 1A is a block diagram of a Parallel Bit Test (PBT) circuit of a semiconductor memory device, according to one embodiment;

FIG. 1B is a block diagram of a semiconductor memory system according to one embodiment;

FIG. 2 is a block diagram of a PBT circuit of a semiconductor memory device, according to one embodiment;

FIG. 3A is a block diagram of a PBT circuit of a semiconductor memory device, according to one embodiment;

FIG. 3B is an exemplary timing diagram illustrating a comparison signal COMP, a clock signal CLK, and an inversion signal INVS when there are no bad memory cells in a plurality of memory cell groups according to one embodiment;

FIG. 3C is an exemplary timing diagram illustrating a comparison signal COMP, a clock signal CLK, and an inversion signal INVS when there is one bad memory cell group in a plurality of memory cell groups according to one embodiment;

FIG. 4A is a block diagram of a PBT circuit of a semiconductor memory device, according to another embodiment;

FIG. 4B is an exemplary timing diagram illustrating a comparison signal COMP, a clock signal CLK, a select signal SEL, a clock select signal CSEL, and an inversion signal INVS when there are no bad memory cells in a plurality of memory cell groups according to one embodiment;

FIG. 4C is an exemplary timing diagram illustrating a comparison signal COMP, a clock signal CLK, a select signal SEL, a clock select signal CSEL, and an inversion signal INVS when there is one bad memory cell group in a plurality of memory cell groups according to one embodiment;

FIG. 5 is a block diagram of a PBT circuit of a semiconductor memory device, according to one embodiment;

FIG. 6A is a block diagram of a PBT circuit of a semiconductor memory device, according to one embodiment;

FIG. 6B is an exemplary timing diagram illustrating an inversion signal INVS, a strobe signal STRB, and a determination signal DET when there are no bad memory cells in a plurality of memory cell groups and the inversion signal INVS inverted in every two periods synchronizes with the strobe signal STRB according to one embodiment;

FIG. 6C is an exemplary timing diagram illustrating an inversion signal INVS, a strobe signal STRB, and a determination signal DET when there are no bad memory cells in a plurality of memory cell groups and the one-period delayed inversion signal INVS inverted in every two periods does not synchronize with the strobe signal STRB according to one embodiment;

FIG. 6D is an exemplary timing diagram illustrating an inversion signal INVS, a strobe signal STRB, and a determination signal DET when a memory cell corresponding to an (n+3)th period is bad from among a plurality of memory cell groups and the inversion signal INVS inverted in every two periods synchronizes with the strobe signal STRB according to one embodiment;

FIG. 6E is an exemplary timing diagram illustrating an inversion signal INVS, a strobe signal STRB, and a determination signal DET when a memory cell corresponding to an (n+3)th period is bad from among a plurality of memory cell groups and the one-period delayed inversion signal INVS inverted in every two periods does not synchronize with the strobe signal STRB according to one embodiment;

FIG. 7A is a block diagram of a PBT circuit of a semiconductor memory device, according to one embodiment;

FIG. 7B is an exemplary timing diagram illustrating an inversion signal INVS, a strobe signal STRB, and a determination signal DET when there are no bad memory cells in a plurality of memory cell groups and the inversion signal INVS inverted in every four periods synchronizes with the strobe signal STRB according to one embodiment;

FIG. 7C is an exemplary timing diagram illustrating an inversion signal INVS, a strobe signal STRB, and a determination signal DET when there are no bad memory cells in a plurality of memory cell groups and the one-period delayed strobe signal STRB does not synchronize with the inversion signal INVS inverted in every four periods according to one embodiment;

FIG. 7D is an exemplary timing diagram illustrating an inversion signal INVS, a strobe signal STRB, and a determination signal DET when a memory cell corresponding to an (n+5)th period is bad from among a plurality of memory cell groups and the inversion signal INVS inverted in every four periods synchronizes with the strobe signal STRB according to one embodiment;

FIG. 7E is an exemplary timing diagram illustrating an inversion signal INVS, a strobe signal STRB, and a determination signal DET when a memory cell corresponding to an (n+5)th period is bad from among a plurality of memory cell groups and the one-period delayed strobe signal STRB does not synchronize with the inversion signal INVS inverted in every four periods according to one embodiment;

FIG. 8 is a block diagram of a semiconductor memory device according to one embodiment; and

FIG. 9 is a flowchart illustrating a method of determining whether at least one memory cell of a semiconductor memory device is a bad cell according to one embodiment.

### DETAILED DESCRIPTION OF THE EMBODIMENTS

Exemplary embodiments will now be described in detail with reference to the accompanying drawings. The present disclosure may allow various kinds of change or modification and various changes in form, and specific embodiments will be illustrated in drawings and described in detail in the specification. However, it should be understood that the specific embodiments do not limit the disclosure to a specific disclosing form but include every modified, equivalent, or replaced one within the spirit and technical scope of the disclosure. Like reference numerals in the drawings denote like elements. In the drawings, dimensions of structures are magnified or reduced than real ones for clarity.

The terminology used in the application is used only to describe specific embodiments and does not necessarily have any intention to limit the disclosure. An expression in the singular includes an expression in the plural unless they are clearly different from each other in a context. In the application, it should be understood that terms, such as ‘comprise,’ ‘include’ and ‘have’, are used to indicate the existence of an implemented feature, number, step, operation, element, part, or a combination of them without excluding in advance the possibility of existence or addition of one or more other features, numbers, steps, operations, elements, parts, or combinations of them.

Although terms, such as ‘first’ and ‘second’, can be used to describe various elements, the elements are not necessarily limited by the terms. In some instance, the terms are used simply to differentiate a certain element from another element. For example, a first element can be named a second element without leaving from the right scope of the disclosure, and likely the second element can be named the first element.

As used herein, the singular forms “a,” “an” and “the” are intended to include the plural forms as well, unless the context clearly indicates otherwise.

All terms used herein including technical or scientific terms have the same meaning as those generally understood by those of ordinary skill in the art unless they are defined differently. It should be understood that terms generally used, which are defined in a dictionary, have the same meaning as in a context of related technology, and the terms are not understood as ideal or excessively formal meaning unless they are clearly defined in the application.

Expressions such as “at least one of,” when preceding a list of elements, modify the entire list of elements and do not modify the individual elements of the list.

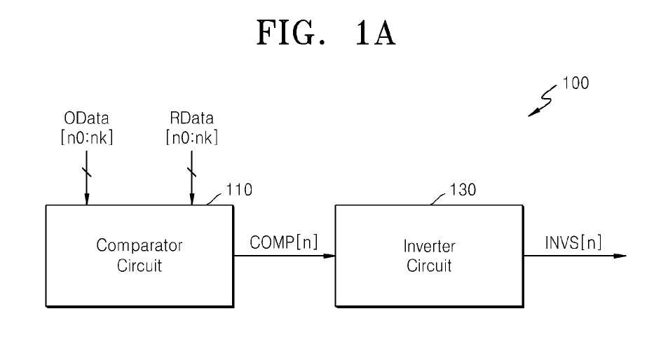

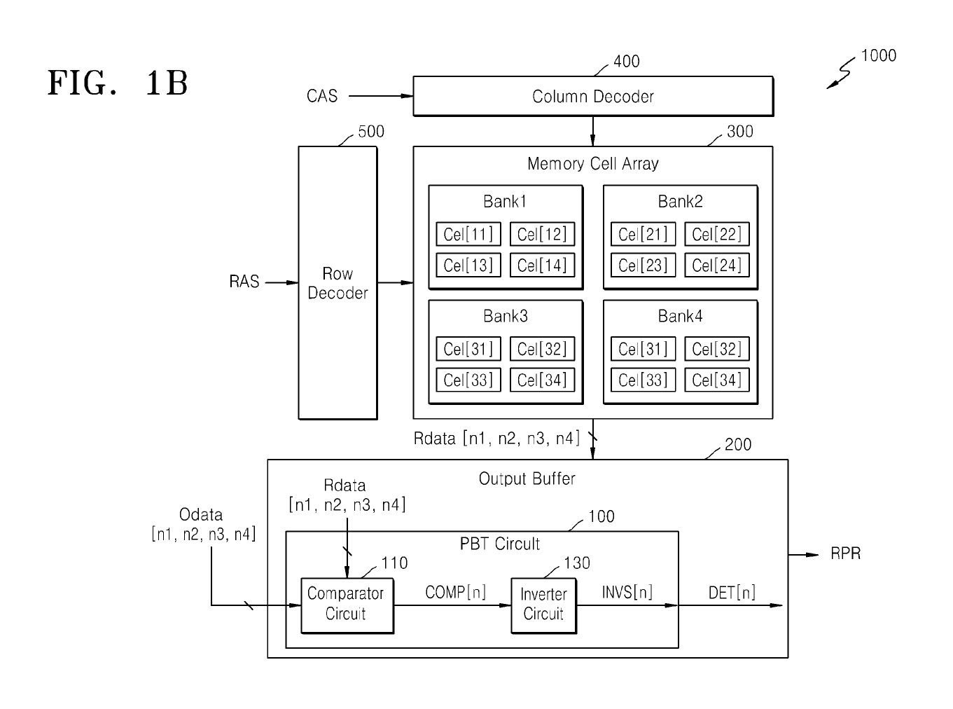

FIG. 1A is a block diagram of a Parallel Bit Test (PBT) circuit 100 of a semiconductor memory device, according to one embodiment.

Referring to FIG. 1A, the PBT circuit 100 includes a comparator circuit 110 and an inverter circuit 130.

The comparator circuit 110 receives a plurality of pieces of original data Odata[n0:nk] (k is an integer equal to or greater than 0) and a plurality of pieces of read data Rdata[n0:nk]. In this case, the plurality of pieces of original data Odata[n0:nk] may be non-error data stored in a separate buffer. The comparator circuit 110 generates a comparison signal COMP[n] based on the plurality of pieces of original data Odata[n0:nk] and the plurality of pieces of read data Rdata[n0:nk]. For example, n may correspond to a group of word lines or group of banks of the semiconductor memory device.

The plurality of pieces of original data Odata[n0:nk] are data written on some memory cells of an nth memory cell group of a memory cell array. A memory cell group is a memory cell unit used for comparison when the comparator circuit 110 generates one period of a comparison signal COMP. One period of the comparison signal COMP is a duration time of the comparison signal COMP[n] when the comparison signal COMP[n] is generated as a comparison result of the plurality of pieces of original data Odata[n0:nk] and the plurality of pieces of read data Rdata[n0:nk]. In this case, the duration time of the comparison signal COMP[n] may be the same as a duration time of a comparison signal COMP[n+1]. The plurality of pieces of read data Rdata[n0:nk] are obtained by reading data written on the nth memory cell group of the memory cell array. If there is no bad (or, failed) memory cell in a plurality (k+1) of memory cells of the nth memory cell group, the plurality of pieces of original data Odata[n0:nk] are identical to the plurality of pieces of read data Rdata[n0:nk]. If a kth memory cell is bad, the original data Odata[nk] is not identical to the read data Rdata[nk] in the kth memory cell.

The bad or failed memory cell may indicate, for example, that the memory cell does not properly read written data. For example, if a memory cell from which the read data Rdata[0] is bad and memory cells from which the remaining read data Rdata[1:k] are good, the original data Odata[0] is not identical to the read data Rdata[0], and the original data Odata[1:k] are identical to the read data Rdata[1:k], respectively.

The comparator circuit 110 may compare the original data Odata[n0:nk] with the read data Rdata[n0:nk] and output the comparison signal COMP[n] during an nth period. When any one of the (k+1) memory cells is bad, the comparator circuit 110 may generate the comparison signal COMP[n] (n is an integer equal to or greater than 0) by indicating a corresponding memory cell group as bad. The comparator circuit 110 compares the original data Odata[nk] with the read data Rdata[nk], and when not one of the (k+1) memory cells is bad, the comparator circuit 110 generates the comparison signal COMP[n] by indicating a corresponding memory cell group as good.

The inverter circuit 130 receives the comparison signal COMP[n] and generates an inversion signal INVS[n] corresponding to the comparison signal COMP[n]. The inversion signal INVS[n] may be generated by inverting and non-inverting the comparison signal COMP[n] in a predefined method.

For example, the inverter circuit 130 may generate an inversion signal INVS by inverting a comparison signal COMP in every two periods. In more detail, the inverter circuit 130 may generate an inversion signal INVS [n−1] by inverting a comparison signal COMP[n−1] and generate an inversion signal INVS[n] without inverting a comparison signal COMP[n]. In addition, the inverter circuit 130 may generate an inversion signal INVS[n+1] by inverting a comparison signal COMP[n+1] and generate an inversion signal INVS[n+2] without inverting a comparison signal COMP[n+2].

As another example, the inverter circuit 130 may generate an inversion signal INVS by inverting a comparison signal COMP in every four periods. In more detail, the inverter circuit 130 may generate an inversion signal INVS[n−1] by inverting a comparison signal COMP[n−1] and generate inversion signals INVS[n], INVS[n+1], and INVS [n+2] without inverting comparison signals COMP[n], COMP[n+1], and COMP[n+2], respectively. In addition, the inverter circuit 130 may generate an inversion signal INVS[n+3] by inverting a comparison signal COMP[n+3] and generate inversion signals INVS[n+4], INVS[n+5], and INVS[n+6] without inverting comparison signals COMP[n+4], COMP[n+5], and COMP[n+6], respectively.

The PBT circuit 100 may check which memory cell group corresponds to each of the inversion signals INVS[n], INVS[n+1], INVS[n+2], . . . , INVS[n+i] (i is an integer equal to or greater than 1) by generating the inversion signals INVS[n:n+i]. Thus, the PBT circuit 100 may correctly check which portion of the memory cell array is bad. Furthermore, since a bad memory cell group checked in this manner may be repaired, a memory cell array to which the bad memory cell group belongs does not have to be discarded, so productivity of semiconductor packages may increase. In addition, since a strobe time may be reduced, a test time may be reduced.

The PBT circuit 100 will be described in more detail.

FIG. 1B is a block diagram of a semiconductor memory system 1000 according to one embodiment.

Referring to FIG. 1B, the semiconductor memory system 1000 may include an output buffer 200, a memory cell array 300, a column decoder 400, and a row decoder 500. The output buffer 200 may include the PBT circuit 100.

The PBT circuit 100 may generate a comparison signal COMP[n], an inversion signal INVS [n], a determination signal DET[n], and a repair signal RPR for each of the memory cell groups (e.g., first to fourth banks Bank1 to Bank4) included in the memory cell array 300. For example, for the first bank Bank1, a comparison signal COMP[1], an inversion signal INVS[1], a determination signal DET[1], and a repair signal RPR[1] may be generated. In addition, signals for memory cell groups may be generated in a predefined order. For example, after signals for the first bank Bank1 are generated, signals for the second bank Bank2 may be generated. As another example, signals for the first bank Bank1, signals for the second bank Bank2, signals for the third bank Bank3, and signals for the fourth bank Bank4 may be generated in this order. In detail, the comparison signal COMP[1] for the first bank Bank1, a comparison signal COMP[2] for the second bank Bank2, a comparison signal COMP[3] for the third bank Bank3, and a comparison signal COMP[4] for the fourth bank Bank4 may be generated in this order.

Read data Rdata may include data of each of the memory cells included in the same bank. For example, read data Rdata[11] is obtained by reading data included in a memory cell Cell[11]. Read data Rdata[12] is obtained by reading data included in a memory cell Cell[12]. Read data Rdata[13] is obtained by reading data included in a memory cell Cell[13]. Read data Rdata[14] is obtained by reading data included in a memory cell Cell[14].

For example, reading read data Rdata[n1, n2, n3, n4] may be performed in a general method of reading a semiconductor memory device. For example, the row decoder 500 decodes a row address signal RAS input from a row address buffer (not shown). The decoded row address signal RAS may enable a word line of the memory cell array 300. The column decoder 400 decodes a column address signal CAS. The decoded column address signal CAS may allow an operation of selecting a bit line of the memory cell array 300. Data in a memory cell selected by the row decoder 500 and the column decoder 400 may be provided to the output buffer 200.

The comparator circuit 110 may compare the read data Rdata[n1, n2, n3, n4] with original data Odata[n1, n2, n3, n4], respectively. In this case, the original data Odata[n1, n2, n3, n4] may be non-error data stored in a separate buffer. The comparator circuit 110 may generate a comparison signal COMP[n] by comparing the read data Rdata[n1, n2, n3, n4] with original data Odata[n1, n2, n3, n4], respectively. The inverter circuit 130 may receive the comparison signal COMP[n] and generate an inversion signal INVS[n] by processing the comparison signal COMP[n]. The PBT circuit 100 may generate a determination signal DET[n] corresponding to the inversion signal INVS[n]. The output buffer 200 may generate a repair signal RPR based on the determination signal DET[n]. For example, the repair signal RPR may include information regarding which bank is replaced with a redundancy bank. Furthermore, the repair signal RPR may include information regarding which word line in the same bank is replaced with a redundancy word line.

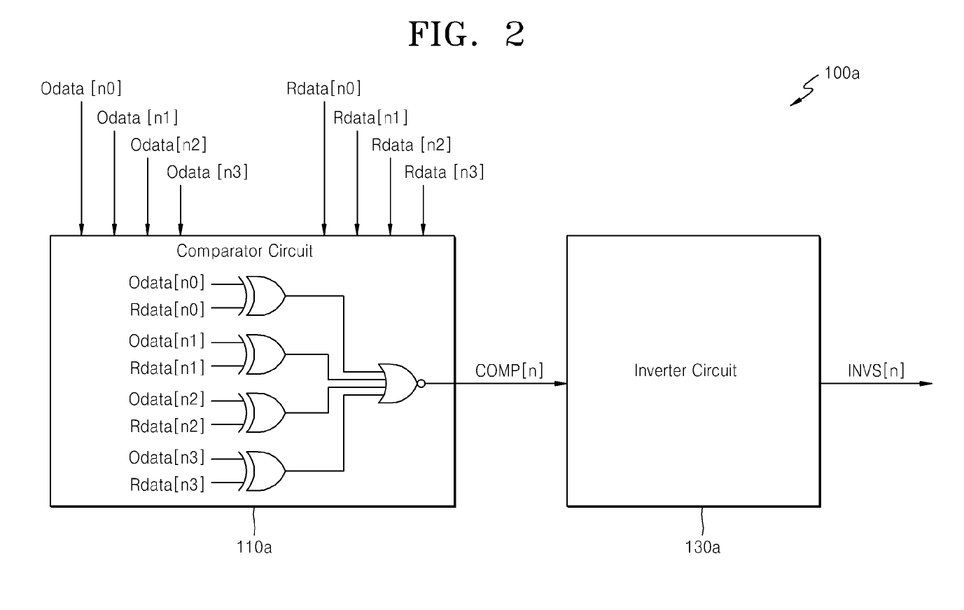

FIG. 2 is a block diagram of a PBT circuit 100a of a semiconductor memory device, according to one embodiment.

Referring to FIG. 2, the PBT circuit 100a includes a comparator circuit 110a and an inverter circuit 130a. The inverter circuit 130a of the PBT circuit 100a performs a similar function to the inverter circuit 130 of the PBT circuit 100.

The comparator circuit 110a of the PBT circuit 100a may include, for example, a plurality of XOR gates. The number of XOR gates may be the same as the number of memory cells included in a memory cell group from which the plurality of pieces of read data Rdata[n0, n1, n2, n3] are read.

Whether the plurality of pieces of read data Rdata[n0, n1, n2, n3] are identical to corresponding pieces of original data Odata[n0, n1, n2, n3] may be determined by an XOR operation and a NOR operation. In more detail, an XOR operation of the original data Odata[n0] and the read data Rdata[n0] may be performed. An XOR operation of the original data Odata[n1] and the read data Rdata[n1] may be performed. An XOR operation of the original data Odata[n2] and the read data Rdata[n2] may be performed. An XOR operation of the original data Odata[n3] and the read data Rdata[n3] may be performed. The results of the XOR operations may be input to a NOR gate. An output of the NOR gate may be a comparison signal COMP[n]. For example, for the memory cell group, if the pieces of original data Odata[n0, n1, n2, n3] are identical to the pieces of read data Rdata[n0, n1, n2, n3] (if there are no bad memory cells), the comparison signal COMP[n] may be output high. The inverter circuit 130a may generate an inversion signal INVS[n] corresponding to the comparison signal COMP[n] by determining in a predefined manner whether the comparison signal COMP[n] is inverted. For example, the inverter circuit 130a may generate the inversion signal INVS[n] by inverting the comparison signal COMP[n] in every two periods. Thus, since each of the inversion signals INVS[n:n+i] has information regarding a corresponding memory cell group, which memory cell group is bad may be checked.

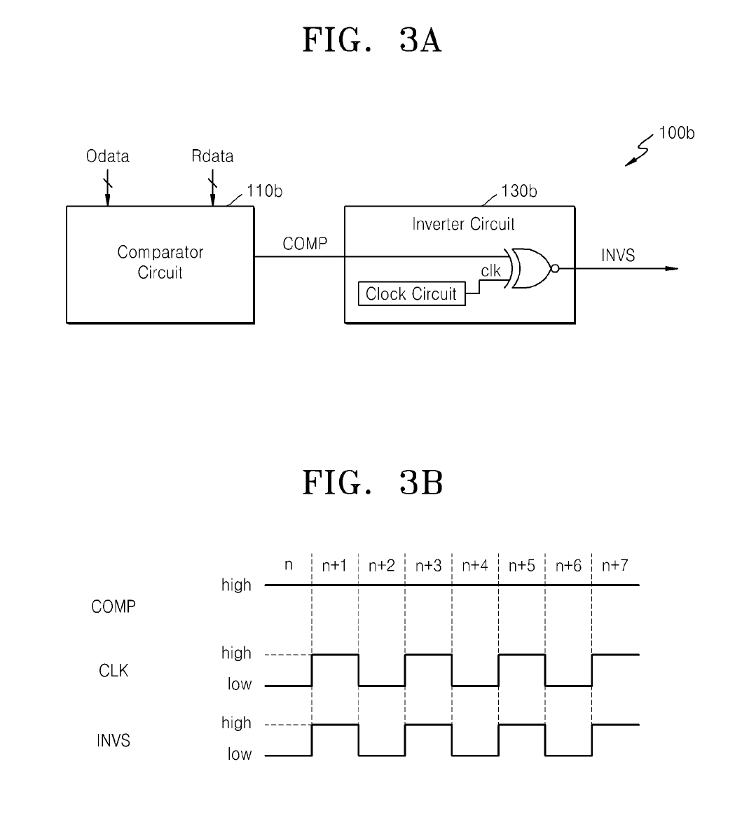

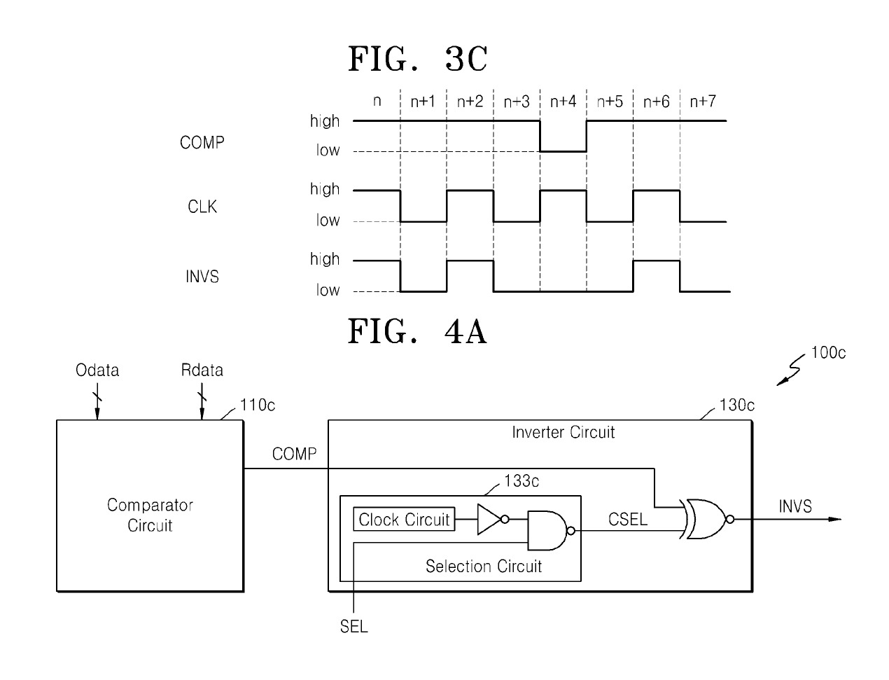

FIG. 3A is a block diagram of a PBT circuit 100b of a semiconductor memory device, according to one embodiment.

Referring to FIG. 3A, the PBT circuit 100b includes a comparator circuit 110b and an inverter circuit 130b. The comparator circuit 110b of the PBT circuit 100b performs a similar function to the comparator circuit 110 of the PBT circuit 100.

The inverter circuit 130b of the PBT circuit 100b may include a clock circuit. The clock circuit generates a clock signal CLK. The clock signal CLK is repeatedly high and low in all periods. The clock signal CLK generated by the clock circuit and a comparison signal COMP are input to an XNOR gate. An output of the XNOR gate is an inversion signal INVS. Thus, the comparison signal COMP may be inverted in every two periods. A detailed operation of the inverter circuit 130b will be described with reference to the timing diagrams below.

FIG. 3B is an exemplary timing diagram illustrating a comparison signal COMP, a clock signal CLK, and an inversion signal INVS when there are no bad memory cells in a plurality of memory cell groups according to one embodiment. The overall comparison signal COMP includes the comparison signals COMP[n] described above. The overall inversion signal INVS includes the inversion signals INVS[n] described above.

Referring to FIG. 3B, since there are no bad memory cells in the plurality of memory cell groups, the comparison signal COMP is continuously high during nth through (n+7)th periods. For example, a subset of memory cells corresponding to the each of the nth through (n+7)th periods are good cells. The clock signal CLK is repeatedly high and low in all of the periods. Since the inversion signal INVS is generated by an XNOR operation of the clock signal CLK and the comparison signal COMP, the inversion signal INVS is repeatedly high and low in all periods with the same phase as that of the clock signal CLK. Thus, the inversion signal INVS has a regular pattern. For example, the inversion signal INVS may have a regular pattern during the nth through (n+7)th periods. Accordingly, the PBT circuit 100b may clearly discriminate between signal periods for the plurality of memory cell groups.

FIG. 3C is an exemplary timing diagram illustrating a comparison signal COMP, a clock signal CLK, and an inversion signal INVS when there is one bad memory cell group in a plurality of memory cell groups according to one embodiment.

Referring to FIG. 3C, at least one memory cell corresponding to a comparison signal COMP of (n+4)th period is bad from among the plurality of memory cell groups. For example, a subset of memory cells corresponding to the (n+4)th period are bad cells. A comparison signal COMP of nth through (n+3)th periods and a comparison signal COMP of (n+5)th through (n+7)th periods are high. The comparison signal COMP of the (n+4)th period is low. The clock signal CLK is repeatedly high and low in all periods. Since an inversion signal INVS is generated by an XNOR operation of the clock signal CLK and the comparison signal COMP, the inversion signal INVS is similar to the case of FIG. 3B except for an inversion signal INVS of the (n+4)th period. The inversion signal INVS of the (n+4)th period is low since a memory cell group corresponding to the comparison signal COMP of the (n+4)th period is a bad cell. For example, the inversion signal INVS may have an irregular pattern during the nth through (n+7)th periods. Accordingly, the PBT circuit 100b may clearly discriminate between signal periods for the plurality of memory cell groups. In addition, the PBT circuit 100b has information regarding the bad memory cell group.

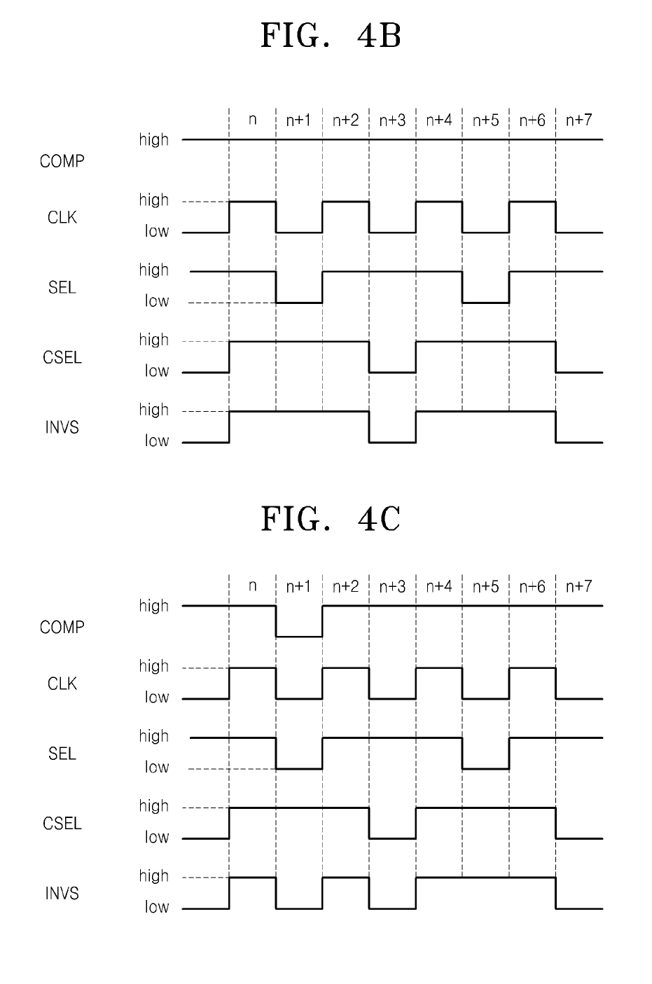

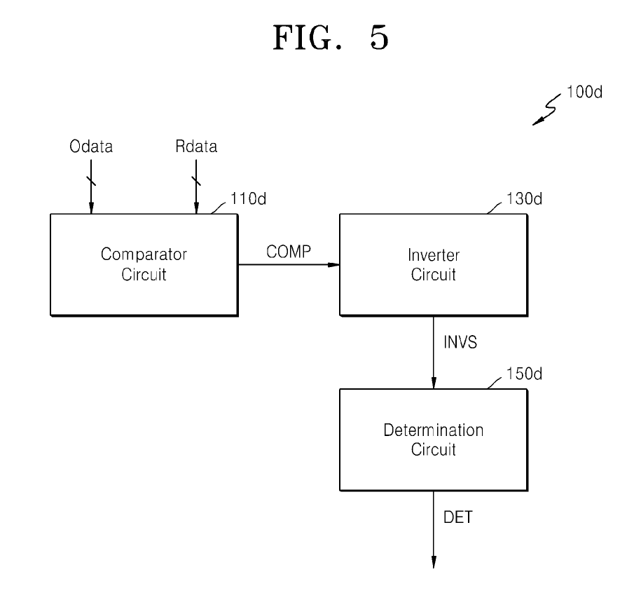

FIG. 4A is a block diagram of a PBT circuit 100c of a semiconductor memory device, according to another embodiment.

Referring to FIG. 4A, the PBT circuit 100c includes a comparator circuit 110c and an inverter circuit 130c. The comparator circuit 110c of the PBT circuit 100c performs a similar function to the comparator circuit 110 of the PBT circuit 100 of FIG. 1A.

The inverter circuit 130c of the PBT circuit 100c may include a selection circuit 133c. The selection circuit 133c receives a select signal SEL and generates a clock select signal CSEL. The select signal SEL may be received at an exterior terminal of the semiconductor memory device (e.g., TMRS). The selection circuit 133c may include a clock circuit. The clock circuit generates a clock signal CLK. The clock signal CLK generated by the clock circuit may be inverted and input to a NAND gate together with the select signal SEL. The clock select signal CSEL and a comparison signal COMP[n] are input to an XNOR gate. Thus, the select signal SEL may be used to determine in how many periods the comparison signal COMP[n] is inverted once.

FIG. 4B is an exemplary timing diagram illustrating a comparison signal COMP, a clock signal CLK, a select signal SEL, a clock select signal CSEL, and an inversion signal INVS when there are no bad memory cells in a plurality of memory cell groups according to one embodiment.

Referring to FIG. 4B, since there are no bad memory cells in the plurality of memory cell groups, the comparison signal COMP is continuously high during nth through (n+7)th periods. The clock signal CLK is repeatedly high and low in the all periods. The select signal SEL is low once in every four periods. The clock select signal CSEL is low once in every four periods. Since the inversion signal INVS is generated by an XNOR operation of the clock signal CLK and the clock select signal CSEL, the inversion signal INVS is low once in every four periods. Thus, the inversion signal INVS may have a regular pattern during the nth through (n+7)th periods. Accordingly, the PBT circuit 100c may check discrimination between signal periods for the plurality of memory cell groups.

FIG. 4C is an exemplary timing diagram illustrating a comparison signal COMP, a clock signal CLK, a select signal SEL, a clock select signal CSEL, and an inversion signal INVS when there is one bad memory cell group in a plurality of memory cell groups according to one embodiment.

Referring to FIG. 4C, at least one memory cell corresponding to a comparison signal COMP of an (n+1)th period is bad from among the plurality of memory cell groups. A comparison signal COMP of an nth period and a comparison signal COMP of (n+2)th through (n+7)th periods are high. The comparison signal COMP of the (n+1)th period is low. The clock signal CLK is repeatedly high and low in all periods. The clock select signal CSEL is low in every four periods. Since the inversion signal INVS is generated by an XNOR operation of the clock signal CLK and the comparison signal COMP, the inversion signal INVS is similar to the case of FIG. 4B except for an inversion signal INVS of the (n+1)th period. Unlike FIG. 4B, the inversion signal INVS of the (n+1)th period is low since a memory cell group corresponding to the comparison signal COMP of the (n+1)th period is bad. Thus, the inversion signal INVS has an irregular pattern during the nth through (n+7)th periods. Accordingly, the PBT circuit 100c may check discrimination between signal periods for the plurality of memory cell groups. In addition, the PBT circuit 100c has information regarding the bad memory cell group.

FIG. 5 is a block diagram of a PBT circuit 100d of a semiconductor memory device, according to another embodiment.

Referring to FIG. 5, the PBT circuit 100d includes a comparator circuit 110d, an inverter circuit 130d, and a determination circuit 150d. The comparator circuit 110d and the inverter circuit 130d of the PBT circuit 100d perform similar functions to the comparator circuit 110 and the inverter circuit 130 of the PBT circuit 100 of FIG. 1A.

The determination circuit 150d receives an inversion signal INVS and generates a determination signal DET. The determination signal DET may include information on whether each memory cell group is bad. The determination signal DET may include information on whether synchronization with the inversion signal INVS is achieved. In addition an output buffer (referring to FIG. 1B) may generate a repair signal RPR based on the determination signal DET.

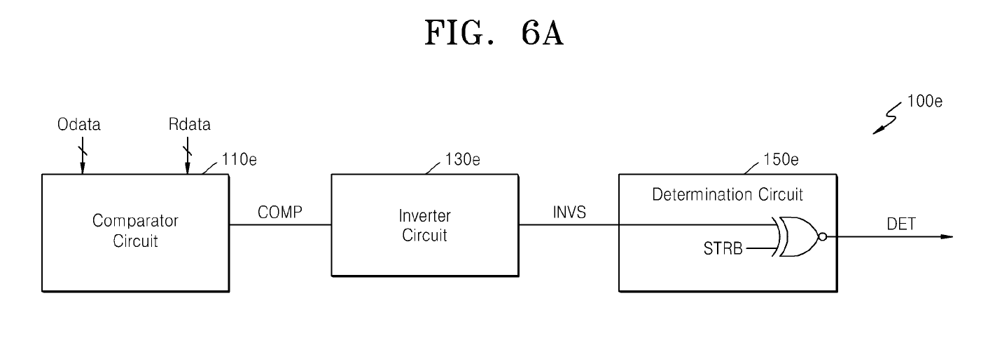

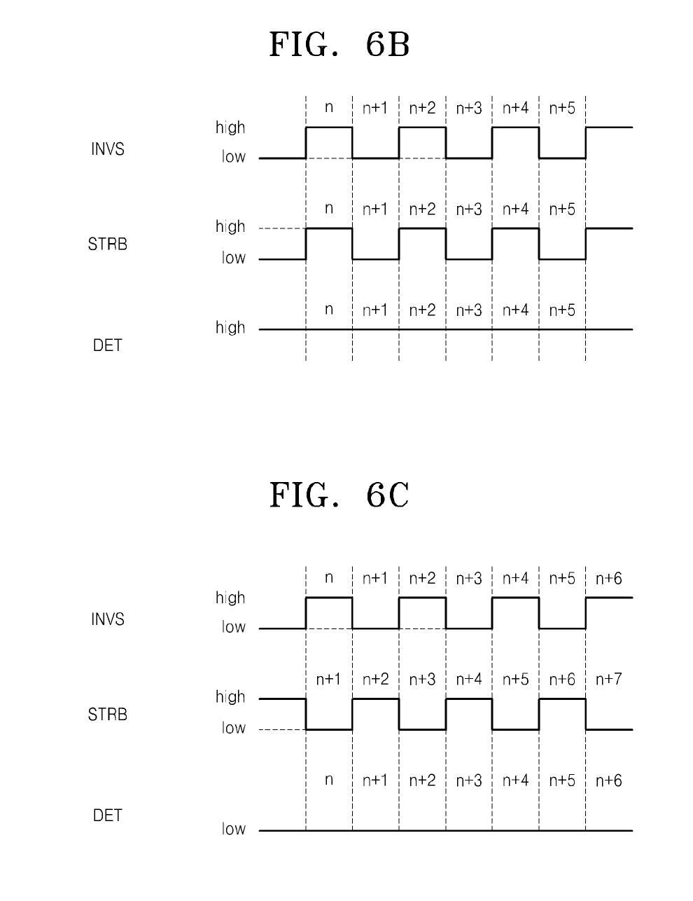

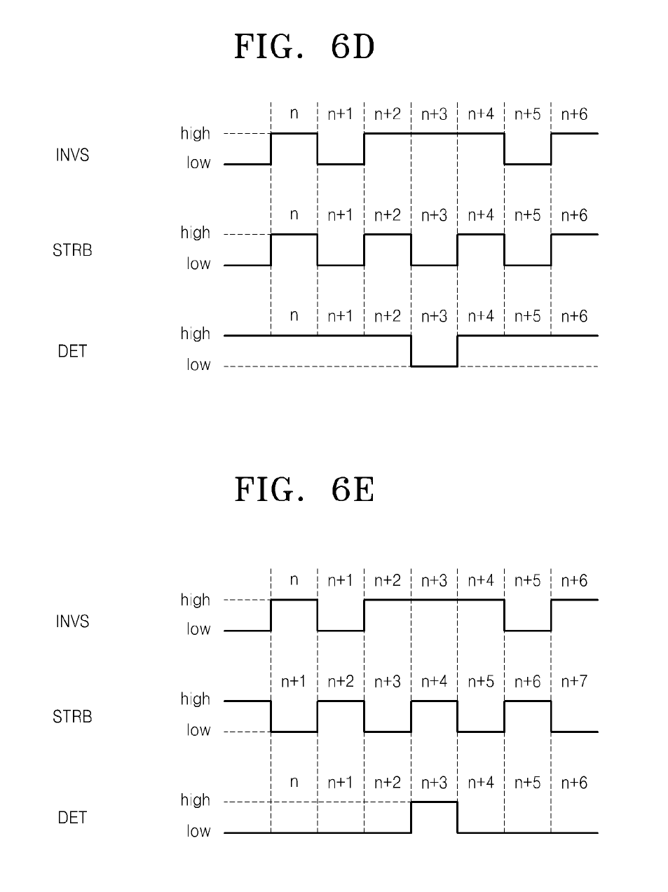

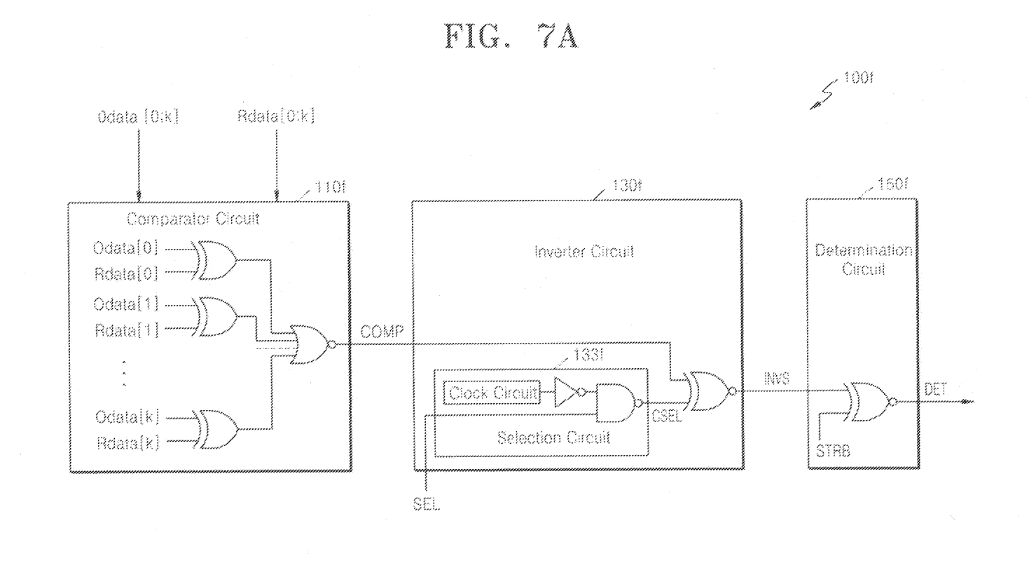

FIG. 6A is a block diagram of a PBT circuit 100e of a semiconductor memory device, according to another embodiment.

Referring to FIG. 6A, the PBT circuit 100e includes a comparator circuit 110e, an inverter circuit 130e, and a determination circuit 150e. The comparator circuit 110e and the inverter circuit 130e of the PBT circuit 100e perform similar functions to the comparator circuit 110 and the inverter circuit 130 of the PBT circuit 100 of FIG. 1A, respectively.

The determination circuit 150e receives an inversion signal INVS and generates a determination signal DET. The inversion signal INVS allows a continuous comparison signal COMP to be clearly discriminated. The determination signal DET is generated by performing an XNOR operation of the inversion signal INVS and a strobe signal STRB. The strobe signal STRB may be received through an exterior terminal of the semiconductor memory device. The strobe signal STRB may be identical to the inversion signal INVS when original data matches with read data in memory cell groups to be read. The determination circuit 150e may generate the determination signal DET by performing an XNOR operation of the inversion signal INVS and the strobe signal STRB. The determination signal DET may include information on whether each memory cell group is bad. For example, if the determination signal DET is high for a plurality of memory cell groups, the plurality of memory cell groups are good. The determination signal DET may include information on whether synchronization with the inversion signal INVS is achieved.

In one embodiment, referring to FIG. 6A, the inversion signal INVS may be output to a tester (not shown) through an exterior terminal of the semiconductor memory device and the determination signal DET may be output from the tester. For example, the determination circuit 150e may be included in the tester.

FIG. 6B is an exemplary timing diagram illustrating an inversion signal INVS, a strobe signal STRB, and a determination signal DET when there are no bad memory cells in a plurality of memory cell groups and the inversion signal INVS inverted in every two periods synchronizes with the strobe signal STRB according to one embodiment.

Referring to FIG. 6B, since there are no bad memory cells in the plurality of memory cell groups, the inversion signal INVS is repeatedly high and low during nth through (n+5)th periods. In addition, the strobe signal STRB is identical to the inversion signal INVS during the nth through (n+5)th periods. Thus, the determination signal DET is high during the nth through (n+5)th periods. Since the determination signal DET is continuously high during the nth through (n+5)th periods, the inversion signal INVS synchronizes with the strobe signal STRB, and an output buffer (not shown) may determine that there are no bad memory cells corresponding to the nth through (n+5)th periods.

FIG. 6C is an exemplary timing diagram illustrating an inversion signal INVS, a strobe signal STRB, and a determination signal DET when there are no bad memory cells in a plurality of memory cell groups and the one-period delayed inversion signal INVS inverted in every two periods does not synchronize with the strobe signal STRB according to one embodiment.

Referring to FIG. 6C, since there are no bad memory cells in the plurality of memory cell groups, the inversion signal INVS is repeatedly high and low during nth through (n+6)th periods. In addition, the strobe signal STRB does not synchronize with the inversion signal INVS. Thus, the determination signal DET is low. Since the determination signal DET is continuously low during the nth through (n+6)th periods, the inversion signal INVS does not synchronize with the strobe signal STRB, and an output buffer (not shown) may determine that there are no bad memory cells.

FIG. 6D is an exemplary timing diagram illustrating an inversion signal INVS, a strobe signal STRB, and a determination signal DET when at least one memory cell corresponding to an (n+3)th period is bad from among a plurality of memory cell groups and the inversion signal INVS inverted in every two periods synchronizes with the strobe signal STRB.

Referring to FIG. 6D, the at least one memory cell corresponding to the (n+3)th period is bad from among the plurality of memory cell groups, and an inversion signal INVS of nth through (n+6)th periods except for the (n+3)th period is repeatedly high and low in all periods. Unlike FIG. 6B, an inversion signal INVS of the (n+3)th period is high. In addition, the strobe signal STRB is the same as that of FIG. 6B. Thus, the determination signal DET is continuously high in nth to (n+6)th periods except for the (n+3)th period. Since the determination signal DET is continuously high except for the (n+3)th period, the inversion signal INVS synchronizes with the strobe signal STRB except for the (n+3)th period, and an output buffer (not shown) may determine that the memory cell corresponding to the (n+3)th period is bad.

FIG. 6E is an exemplary timing diagram illustrating an inversion signal INVS, a strobe signal STRB, and a determination signal DET when at least one memory cell corresponding to an (n+3)th period is bad from among a plurality of memory cell groups and the one-period delayed inversion signal INVS inverted in every two periods does not synchronize with the strobe signal STRB.

Referring to FIG. 6E, the at least one memory cell corresponding to the (n+3)th period is bad from among the plurality of memory cell groups, and an inversion signal INVS of nth through (n+6)th periods except for the (n+3)th period is repeatedly high and low in all periods. Unlike FIG. 6C, an inversion signal INVS of (n+3)th is high. In addition, the strobe signal STRB is the same as that of FIG. 6C. Thus, the determination signal DET is continuously low in nth to (n+6)th periods except for the (n+3)th period. Since the determination signal DET is continuously low except for the (n+3)th period, the inversion signal INVS does not synchronize with the strobe signal STRB except for the (n+3)th period, and an output buffer (not shown) may determine that the memory cell corresponding to the (n+3)th period is bad.

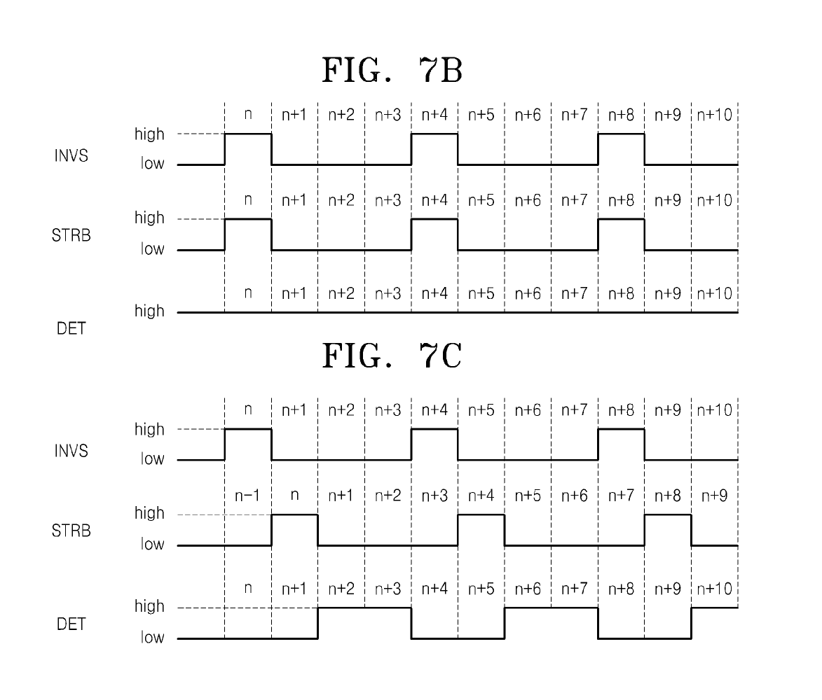

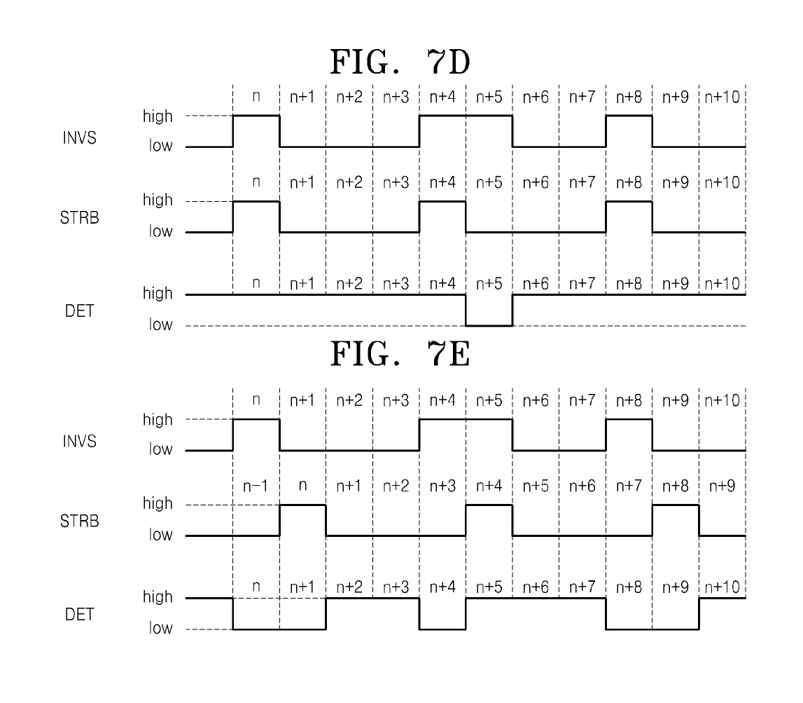

FIG. 7A is a block diagram of a PBT circuit 100f of a semiconductor memory device, according to another embodiment.

Referring to FIG. 7A, the PBT circuit 100f includes a comparator circuit 110f, an inverter circuit 130f, and a determination circuit 150f. The comparator circuit 110f of the PBT circuit 100f performs a similar function to the comparator circuit 110a of the PBT circuit 100a of FIG. 2. The inverter circuit 130f of the PBT circuit 100f performs a similar function to the inverter circuit 130e of the PBT circuit 100e of FIG. 6A. The determination circuit 150f of the PBT circuit 100f performs a similar function to the determination circuit 150e of the PBT circuit 100e of FIG. 6A. Operations of the PBT circuit 100f will now be described in detail below.

FIG. 7B is an exemplary timing diagram illustrating an inversion signal INVS, a strobe signal STRB, and a determination signal DET when there are no bad memory cells in a plurality of memory cell groups and the inversion signal INVS inverted once in every four periods synchronizes with the strobe signal STRB according to one embodiment.

Referring to FIG. 7B, since there are no bad memory cells in the plurality of memory cell groups, the inversion signal INVS is high once in every four periods during nth through (n+10)th periods. In addition, the strobe signal STRB is identical to the inversion signal INVS. Thus, the determination signal DET is continuously high during nth through (n+10)th periods. Since the determination signal DET is continuously high, the inversion signal INVS synchronizes with the strobe signal STRB, and an output buffer (not shown) may determine that there are no bad memory cells.

FIG. 7C is an exemplary timing diagram illustrating an inversion signal INVS, a strobe signal STRB, and a determination signal DET when there are no bad memory cells in a plurality of memory cell groups and the one-period delayed strobe signal STRB (or, one-period preceded inversion signal INVS) does not synchronize with the inversion signal INVS inverted once in every four periods.

Referring to FIG. 7C, since there are no bad memory cells in the plurality of memory cell groups, the inversion signal INVS is high once in every four periods. In addition, the strobe signal STRB is delayed by one period compared to the inversion signal INVS and does not synchronize with the inversion signal INVS. Thus, as shown in FIG. 7C, a determination signal DET of nth, (n+1)th, (n+4)th, (n+5)th, (n+8)th, and (n+9)th is low, and a determination signal DET of (n+2)th, (n+3)th, (n+6)th, (n+7)th, and (n+10)th periods is high. Since the determination signal DET is repeatedly low and high in a regular pattern, the inversion signal INVS does not synchronize with the strobe signal STRB, and an output buffer (not shown) may determine that there are no bad memory cells.

FIG. 7D is an exemplary timing diagram illustrating an inversion signal INVS, a strobe signal STRB, and a determination signal DET when at least one memory cell corresponding to an (n+5)th period is bad cell from among a plurality of memory cell groups and the inversion signal INVS inverted once in every four periods synchronizes with the strobe signal STRB.

Referring to FIG. 7D, at least one memory cell corresponding to the (n+5)th period is a bad cell from among the plurality of memory cell groups, and an inversion signal INVS of nth, (n+4)th, (n+5)th, and (n+8)th periods is high. Unlike FIG. 7B, an inversion signal INVS of the (n+5)th period is high since a corresponding memory cell is a bad cell. In addition, the strobe signal STRB is the same as that of FIG. 7B. Thus, the determination signal DET is continuously high during nth to (n+10)th periods except for the (n+5)th period. Since the determination signal DET is continuously high except for the (n+5)th period, the inversion signal INVS synchronizes with the strobe signal STRB except for the (n+5)th period, and an output buffer (not shown) may determine that the memory cell corresponding to the (n+5)th period is a bad cell.

FIG. 7E is an exemplary timing diagram illustrating an inversion signal INVS, a strobe signal STRB, and a determination signal DET when at least one memory cell corresponding to an (n+5)th period is a bad cell from among a plurality of memory cell groups and the one-period delayed strobe signal STRB does not synchronize with the inversion signal INVS inverted once in every four periods.

Referring to FIG. 7E, the at least one memory cell corresponding to the (n+5)th period is a bad cell from among the plurality of memory cell groups, and an inversion signal INVS of nth, (n+4)th, (n+5)th, and (n+8)th periods is high. Unlike FIG. 7C, an inversion signal INVS of the (n+5)th period is high. In addition, the strobe signal STRB is delayed by one period compared to the inversion signal INVS and does not synchronize with the inversion signal INVS. Thus, the determination signal DET is the same as FIG. 7C during nth to (n+10)th periods except for the (n+5)th period. Since the determination signal DET repeats low and high in a regular pattern except for the (n+5)th period, the inversion signal INVS does not synchronize with the strobe signal STRB except for the (n+5)th period, and an output buffer (not shown) may determine that the memory cell corresponding to the (n+5)th period is a bad cell.

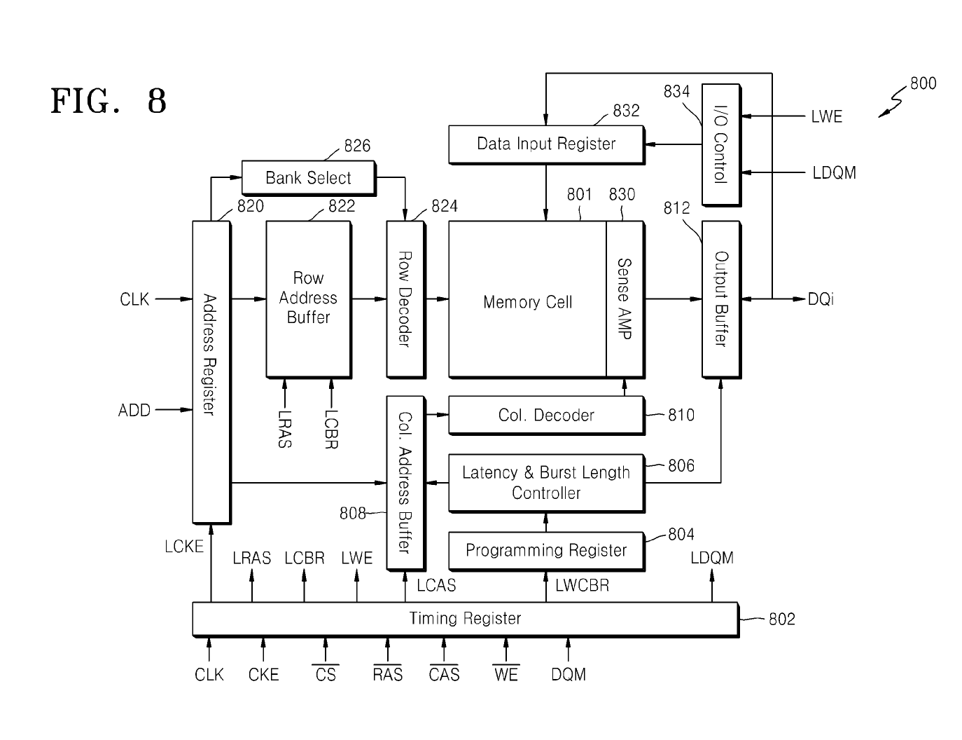

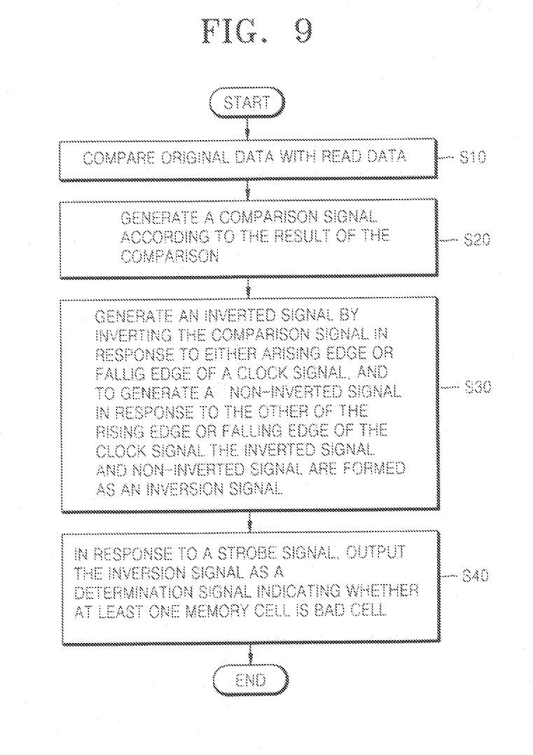

FIG. 8 is a block diagram of a semiconductor memory device 800 according to one embodiment. Referring to FIG. 8, the semiconductor memory device 800 may include the PBT circuit 100, 100a, 100b, 100c, 100d, 100e, or 100f according to one embodiment.

A timing register 802 may be enabled when a chip select signal CS changes from a disabled level (e.g., logic high) to an enabled level (e.g., logic low). The timing register 802 may receive command signals, such as a clock signal CLK, a clock enable signal CKE, a chip select signal CSB, a row address strobe signal RASB, a column address strobe signal CASB, a write enable signal WEB, and a data input/output mask signal DQM, from the outside and may generate various internal command signals LRAS, LCBR, LWE, LCAS, LWCBR, and LDQM for controlling the circuit blocks by processing the received command signals.

Some of the internal command signals LRAS, LCBR, LWE, LCAS, LWCBR, and LDQM generated by the timing register 802 are stored in a programming register 804. For example, latency information and burst length information related to a data output may be stored in the programming register 804. The internal command signals stored in the programming register 804 may be provided to a latency and burst length controller 806, and the latency and burst length controller 806 may provide a control signal for controlling a latency or a burst length of data to a column decoder 810 via a column buffer 808 or to an output buffer 812.

An address register 820 may receive an address signal ADD from the outside. A row address signal may be provided to a row decoder 824 via a row buffer/refresh counter 822. In addition, a column address signal may be provided to the column decoder 810 via the column buffer 808. The row buffer/refresh counter 822 may further receive a refresh address signal generated by a refresh counter in response to a refresh command LRAS or LCBR and may provide any one of the row address signal and the refresh address signal to the row decoder 824. In addition, the address register 820 may provide a bank signal for selecting a bank to a bank selector 826.

The row decoder 824 may decode the row address signal or the refresh address signal input from the row buffer/refresh counter 822 and enable a word line of a memory cell array 801. The column decoder 810 may decode the column address signal and perform an operation of selecting a bit line of the memory cell array 801. For example, a column selection line signal may be applied to the semiconductor memory device 800 to perform a selection operation through the column selection line.

A sense amplifier 830 may amplify data of a memory cell selected by the row decoder 824 and the column decoder 810 and provide the amplified data to an output buffer 812. Data for writing on a memory cell may be provided to the memory cell array 801 via a data input register 832, and an input/output controller 834 may control a data transfer operation through the data input register 832.

FIG. 9 is a flowchart illustrating a method for testing the operation of a semiconductor memory device according to one embodiment.

Referring to FIG. 9, in operation S10, original data to be written on memory cells is compared with read data from the memory cells. According to the result of the comparison, a comparison signal is generated during n periods in operation S20. In operation S30, an inverted signal is generated by inverting the comparison signal in response to either a rising edge or a falling edge of a clock signal and a non-inverted signal is generated in response to the other of the rising edge or falling edge of the clock signal. The inverted signal and non-inverted signal are formed as an inversion signal. In operation S40, the inversion signal is output as a determination signal in response to a strobe signal. The determination signal indicates whether at least one memory cell corresponding to each period is bad cell.

While the disclosure has been particularly shown and described with reference to exemplary embodiments thereof, it will be understood that various changes in form and details may be made therein without departing from the spirit and scope of the following claims.

What is claimed is:

1. A circuit for a Parallel Bit Test (PBT) of a semiconductor memory device including a memory cell array, the PBT circuit comprising:
a comparator circuit configured to generate a comparison signal responsive to a comparison indicating that first data to be written in a first group of the memory cells are the same as second data read from the first group of the memory cells, wherein the comparison signal includes n periods, wherein the value of the comparison signal during each period corresponds to a subset of the first group of the memory cells, and wherein the n is a natural number; and
an inverter circuit configured to generate during each period, an inverted signal by inverting the comparison signal in response to either a rising edge or a falling edge of a clock signal, and to generate a non-inverted signal in response to the other of the rising edge or falling edge of the clock signal, the inverted signal and non-inverted signal forming an inversion signal indicating whether at least one cell corresponding to each period is a bad cell.

2. The PBT circuit of claim 1, wherein the inversion signal is synchronized with the clock signal when the first data are the same as the second data.

3. The PBT circuit of claim 1, wherein the inverter circuit is configured to generate the inversion signal by performing an XNOR operation of the comparison signal and the clock signal.

4. The PBT circuit of claim 3, wherein the inverter circuit further comprises:
a selection circuit configured to receive a select signal and the clock signal, and configured to generate a signal for determining whether to invert the comparison signal based on the clock signal.

5. The PBT circuit of claim 1, wherein the subset of memory cells associated with each period corresponds to a word line or a bank of the memory cell array.

6. The PBT circuit of claim 1, further comprising a determination circuit configured to output the inversion signal as a determination signal in response to a strobe signal, wherein the determination signal indicates whether at least one cell corresponding to each period is a bad cell.

7. The PBT circuit of claim 6, wherein the determination circuit is configured to generate the determination signal by performing an XNOR operation of the inversion signal and the strobe signal, and the strobe signal is the same as the inversion signal when the first data are the same as the second data.

8. The PBT circuit of claim 6, wherein the determination signal has an irregular pattern when at least one cell from the first group of memory cells is a bad memory cell.

9. A memory system comprising:
the PBT circuit of claim 1; and
a determination circuit configured to output the inversion signal as a determination signal in response to a strobe signal, wherein the determination signal indicates whether at least one cell corresponding to each period is a bad memory cell.

10. The PBT circuit of claim 9, wherein the determination signal has an irregular pattern when at least one cell from the first group of memory cells is a bad memory cell.

11. The PBT circuit of claim 1, configured so that the comparison signal includes a different logic value from a predetermined logic value for at least one period when a corresponding memory cell is a bad memory cell.

12. A circuit of a semiconductor memory device including a memory cell array, the circuit comprising:
a comparator circuit configured to generate a comparison signal responsive to a comparison indicating that first data to be written on a first group of memory cells of the memory cell array are the same as read data from the first group of the memory cells;
an inverter circuit configured to generate an inverted signal by inverting the comparison signal in response to either a rising edge or a falling edge of a clock signal, and to generate a non-inverted signal in response to the other of the rising edge or falling edge of the clock signal, the inverted signal and non-inverted signal forming an inversion signal; and
a determination circuit configured to output the inversion signal as a determination signal in response to a strobe signal, wherein the determination signal indicates whether at least one memory cell is a bad memory cell.

13. The circuit of claim 12, wherein the inverter circuit is further configured to generate the inversion signal in response to a selection signal.

14. The circuit of claim 12, configured so that the comparison signal includes a different logic value from a predetermined logic value for at least one period when corresponding memory cell is a bad memory cell.

15. A method for testing the operation of a semiconductor device including a plurality of memory cells, the method comprising:
comparing first data to be written in a first group of the memory cells with read data stored in the first group of the memory cells;
generating a comparison signal in response to the result of the comparing during first through nth periods, a subset of memory cells of the first group corresponding to each of the first through nth periods, respectively; and
generating an inverted signal by inverting the comparison signal in response to either a rising edge or a falling edge of a clock signal, and to generate a non-inverted signal in response to the other of the rising edge or falling edge of the clock signal, the inverted signal and non-inverted signal forming an inversion signal,
wherein the inversion signal indicates whether at least one cell corresponding to each period is a bad memory cell.

16. The method of claim 15, further comprising:
outputting a determination signal in response to the inversion signal and a strobe signal,
wherein the determination signal indicates whether at least one cell corresponding to each period is a bad memory cell.

17. The method of claim 16, wherein generating the inversion signal further comprises selecting an inversion of the comparison signal in response to a selection signal.

18. The method of claim 15, wherein the comparison signal includes either a logic high level or logic low level when the first data is the same as the read data.

19. The method of claim 15, wherein the inversion signal is the same as the clock signal when the first data is the same as the read data.

20. The method of claim 15, wherein the determination signal has an irregular pattern when at least one cell from the each subset of memory cells is a bad memory cell.
